(19) United States
(12) Patent Application Publication
(10) Pub. No.: US 2013/0135014 A1
(43) Pub. Date: May 30, 2013

(54) Driver Circuit

(71) Applicants: Po-Hsin LIN, HSINCHU (TW); Chi-Liang WU, HSINCHU (TW); Chin-Wen LIN, HSINCHU (TW); Ted-Hong SHINN, HSINCHU (TW)

(72) Inventors: Po-Hsin LIN, HSINCHU (TW); Chi-Liang WU, HSINCHU (TW); Chin-Wen LIN, HSINCHU (TW); Ted-Hong SHINN, HSINCHU (TW)

(73) Assignee: E INK HOLDINGS INC., HSINCHU (TW)

(21) Appl. No.: 13/565,807

(22) Filed: Aug. 3, 2012

(30) Foreign Application Priority Data
Nov. 25, 2011 (TW) 100143406

(51) Int. Cl. H03K 3/00

(52) U.S. Cl. 327/111

(57) ABSTRACT

A driver circuit is provided. The driver circuit includes a first transistor for receiving a preceding gate signal to generate a first control signal, a second transistor for pulling down the first control signal according to a second control signal, a third transistor for outputting a clock signal according to the first control signal, a fourth transistor for pulling down the clock signal according to the second control signal, a fifth transistor connected to a high voltage source for outputting the second control signal, a sixth transistor for pulling down the second control signal according to the first control signal, a seventh transistor for receiving a next gate signal to pull down the first control signal, and a capacity. The preceding gate signal charges the capacitor to generate the first control signal.

### RELATED APPLICATIONS

This application claims priority to Taiwan Application Serial Number 100143406, filed Nov. 25, 2011, which is herein incorporated by reference.

### BACKGROUND

1. Field of Invention

The present invention relates to a driver circuit of a display panel, and more particularly to a gate driver circuit directly formed in the display panel.

2. Description of Related Art

With the improvement of techniques for manufacture and design, many new display apparatuses are developed, wherein an electro-phoretic display (EPD) has many advantages including lower energy consumption, longer lifetime, and smaller size.

For reducing manufacturing cost, a new technology of directly forming a gate driver circuit structure on a display panel has replaced a typical technology of using independent gate driver circuits. Such a new technology can save the cost of independent gate driver circuits. Therefore, the manufacturing cost can be reduced.

However, there are gate lines, data lines and pixels formed on the display panel. Therefore, no much space is left for directly forming gate driver circuits on the display panel. Therefore, there is a need to reduce the size of the gate driver circuits.

### SUMMARY

An embodiment of the present invention provides a driver circuit. The driver circuit includes a first transistor for receiving a preceding gate signal to generate a first control signal, a second transistor for pulling down a voltage level of the first control signal according to a second control signal, a third transistor for receiving a clock signal and outputting the clock signal according to the first control signal, a fourth transistor for pulling down a voltage level of the clock signal according to the second control signal, a fifth transistor connected to a high voltage source for outputting the second control signal, a sixth transistor for pulling down a voltage level of the second control signal according to the first control signal, a seventh transistor for receiving a next gate signal to pull down a voltage level of the first control signal to turn off the sixth transistor, wherein a voltage level of the second control signal is pulled up when the sixth transistor is turned off, and a capacitor, wherein the preceding gate signal charges the capacitor to generate the first control signal.

Accordingly, less transistors are used to control the voltage level of the control signal to output a gate signal. The structure of the driver circuit is simple, the size of the driver circuit is reduced, and the size of a display panel containing the driver circuit is also reduced.

### BRIEF DESCRIPTION OF THE DRAWINGS

In order to make the foregoing as well as other aspects, features, advantages, and embodiments of the present invention more apparent, the accompanying drawings are described as follows:

FIG. 1A illustrates a schematic diagram of a driver circuit according to an embodiment of the present invention;

FIG. 1B illustrates a timing diagram for operating the driver circuit in FIG. 1A;

FIG. 2A illustrates a schematic diagram of a driver circuit according to to another embodiment of the present invention;

FIG. 2B illustrates a timing diagram for operating the driver circuit in FIG. 2A;

FIG. 3A illustrates a timing diagram of a first selection signal; and

FIG. 3B illustrates a timing diagram of a second selection signal.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

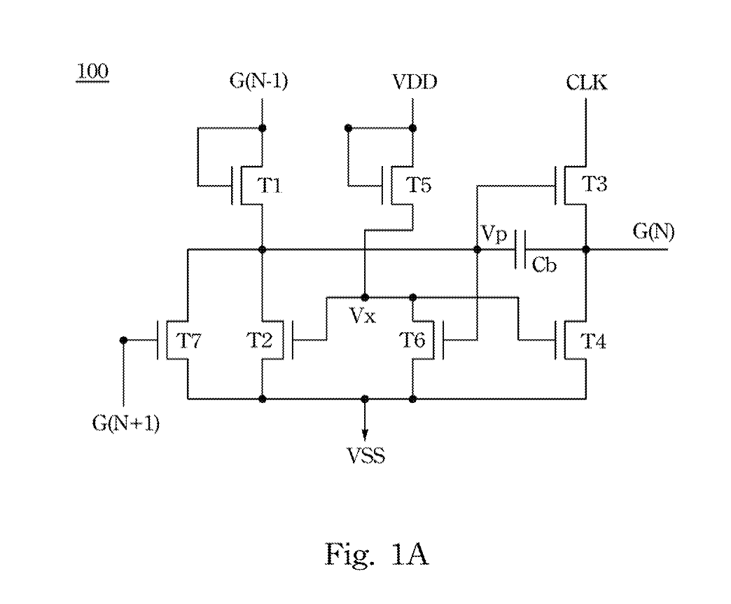

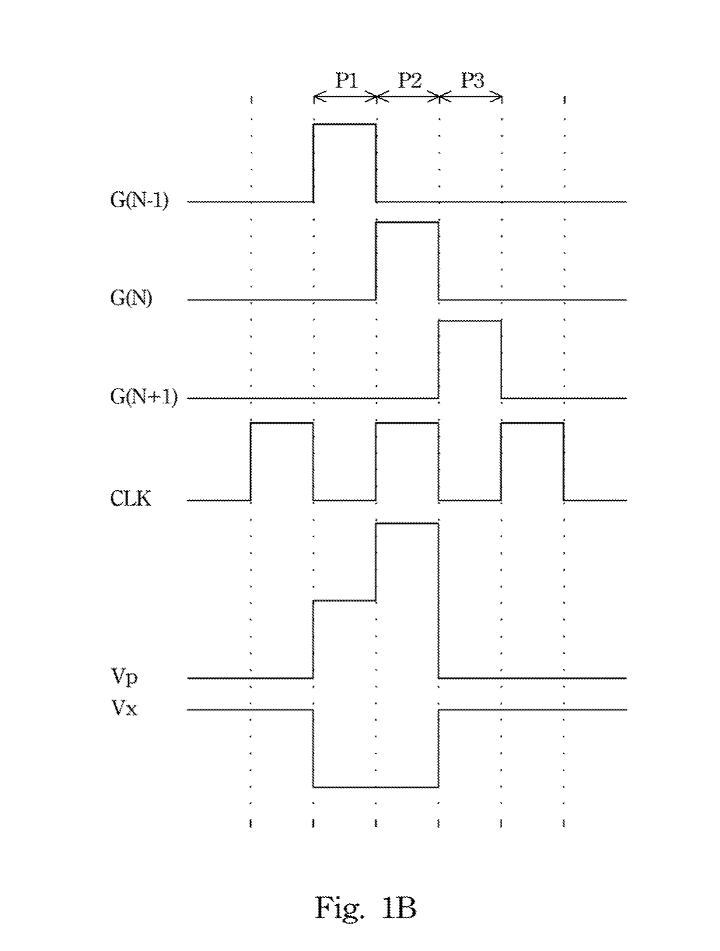

FIG. 1A illustrates a schematic diagram of a driver circuit according to an embodiment of the present invention. The driver circuit 100 includes seven transistors T1, T2, T3, T4, T5, T6 and T7 and a capacitor Cb. The transistors T1, T2, T3, T4, T5, T6 and T7 can be thin film transistors, metal oxide semiconductor field effect transistors or junction field effect transistors. The driver circuit is a gate driver circuit of a display.

The first transistor T1 includes a first end, a second end and a gate end. The first end of the first transistor T1 receives a preceding gate signal G(N−1) from a preceding gate driver circuit. The gate end of the first transistor T1 is connected to the first end of the first transistor T1. The second end of the first transistor T1 is connected to the capacitor Cb. Therefore, the capacitor Cb is charged to generate a control signal Vp (i.e. driving control voltage) according to the preceding gate signal G(N−1) received by the first transistor T1.

The second transistor T2 includes a first end, a second end and a gate end. The first end of the second transistor T2 is connected to the second end of the first transistor T1. The gate end of the second transistor T2 receives a control signal Vx. The second end of the second transistor T2 is connected to a low voltage source VSS to stabilize and pull down the level of the control signal Vp.

The third transistor T3 includes a first end, a second end and a gate end. The first end of the third transistor T3 receives a clock signal CLK. The gate end of the third transistor T3 receives the control signal Vp. The second end of the third transistor T3 outputs a gate signal G(N). The capacitor Cb is connected to the second end of the third transistor T3 and the gate end of the third transistor T3.

The fourth transistor T4 includes a first end, a second end and a gate end. The first end of the fourth transistor T4 is connected to the second end of the third transistor T3. The gate end of the fourth transistor T4 receives the control signal Vx. The second end of the fourth transistor T4 is connected to the low voltage source VSS.

The fifth transistor T5 includes a first end, a second end and a gate end. The first end of the fifth transistor T5 is connected to a high voltage source VDD. The gate end of the fifth transistor T5 is connected to the first end of the fifth transistor T5. The second end of the fifth transistor T5 outputs the control signal Vx according to the high voltage source VDD.

The sixth transistor T6 includes a first end, a second end and a gate end. The first end of the sixth transistor T6 receives the control signal Vx. The gate end of the sixth transistor T6 receives the control signal Vp and is connected to the capacity Cp. The second end of the sixth transistor T6 is connected to the low voltage source VSS.

The seventh transistor T7 includes a first end, a second end and a gate end. The first end of the seventh transistor T7 is connected to the second end of the first transistor T1. The gate end of the seventh transistor T7 receives a next gate signal G(N+1) from a next gate driver circuit. The second end of the seventh transistor T7 is connected to the low voltage source VSS.

When the first end of the first transistor T1 in the gate driver circuit 100 receives the preceding gate signal G(N−1) from the preceding gate driver circuit, if the preceding gate signal G(N−1) is at a high level, the first transistor T1 is turned on because the gate end of the first transistor T1 and the first end of the first transistor T1 are connected together. Then, the capacitor Cb is charged by the high-level preceding gate signal G(N−1) to generate the control signal Vp to turn on the third transistor T3 and the sixth transistor T6. Moreover, the first end of the fifth transistor T5 is connected to the high voltage source VDD. The gate end of the fifth transistor T5 and the first end of the fifth transistor T5 are connected together. Therefore, the control signal Vx outputted from the second end of the fifth transistor T5 is at a high level. However, when the sixth transistor T6 is turned on, the high-level control signal Vx is pulled down by the low voltage source VSS through the turned-on sixth transistor T6. Then, the fourth transistor T4 and the second transistor T2 are turned off by the pulled down control signal Vx to enable the second end of the third transistor T3 to output the clock signal CLK.

When the gate end of the seventh transistor T7 in the gate driver circuit 100 receives the next gate signal G(N+1) from the next gate driver circuit, the seventh transistor T7 is turned on. Then, the high-level control signal Vp is pulled down by the low voltage source VSS through the turned-on seventh transistor T7. Then, the third transistor T3 and the sixth transistor T6 are turned off by the pulled down control signal Vp to enable the second end of the fifth is transistor T5 to output a high-level control signal Vx. Then, the fourth transistor T4 and the second transistor T2 are turned on by the high-level control signal Vx to enable the second end of the third transistor T3 to output a low level signal.

In this embodiment, the control signal Vx is maintained at a high level by the high voltage source VDD through the fifth transistor T5. The fifth transistor T5 and the sixth transistor T6 connected in series control the voltage level of the control signal Vx. The sixth transistor T6 is turned on when the first end of the first transistor T1 receives the preceding gate signal G(N−1) from the preceding gate driver circuit. Then, the high-level control signal Vx is pulled down to enable the second end of the third transistor T3 to output the present gate signal G(N). On the other hand, the sixth transistor T6 is turned off when the gate end of the seventh transistor 17 receives the next gate signal G(N+1) from the next gate driver circuit. Then, the low level control signal Vx is pulled up to enable the second end of the third transistor T3 to output a low level signal. Thus, the circuit structure is very simple. Moreover, the size of the sixth transistor T6 and the fifth transistor T5 can be used to control the time of the control signal Vx which is changed from the high level to the low level or from the low level to the high level. That is, the size of the sixth transistor T6 and the fifth transistor T5 can be used to determine the voltage level of the control signal Vx.

FIG. 1B illustrates a timing diagram for operating the driver circuit in FIG. 1A. In time period P1, the preceding gate signal G(N−1) from the preceding gate driver circuit is transferred to the first end of the first transistor T1 to turn on the first transistor T1. When the preceding gate signal G(N−1) passes through the first transistor T1, the control signal Vp is pulled up to turn on the sixth transistor T6. Then, the control signal Vx is pulled down by the low voltage source VSS through the turned-on sixth transistor T6. The control signal Vp is at a floating state. That is, the voltage level of the control signal Vp is affected by the clock signal CLK through the parasitism capacitor in the third transistor T3. Thus, in time period P2, when the clock signal CLK is at a high level state, the voltage level of the control signal Vp is increased. Moreover, the control signal Vx is maintained at a low level state by the low voltage source VSS through the turned-on sixth transistor T6 to keep the fourth transistor T4 and the second transistor T2 at an off state. Because the third transistor T3 is turned on when the preceding gate signal G(N−1) is transferred to the first transistor T1, the third transistor T3 outputs the gate signal G(N) synchronized to the clock signal CLK after the preceding gate signal G(N−1). That is, the gate signal G(N) is generated in time period P2. In time period P3, the clock signal CLK is at a low level state and the next gate signal G(N+1) from the next gate driver circuit is transferred to the seventh transistor T7 to turn on the seventh transistor T7. The control signal Vp is pulled down by the low voltage source VSS through the turned-on seventh transistor T7. That is, the control signal Vp is reset.

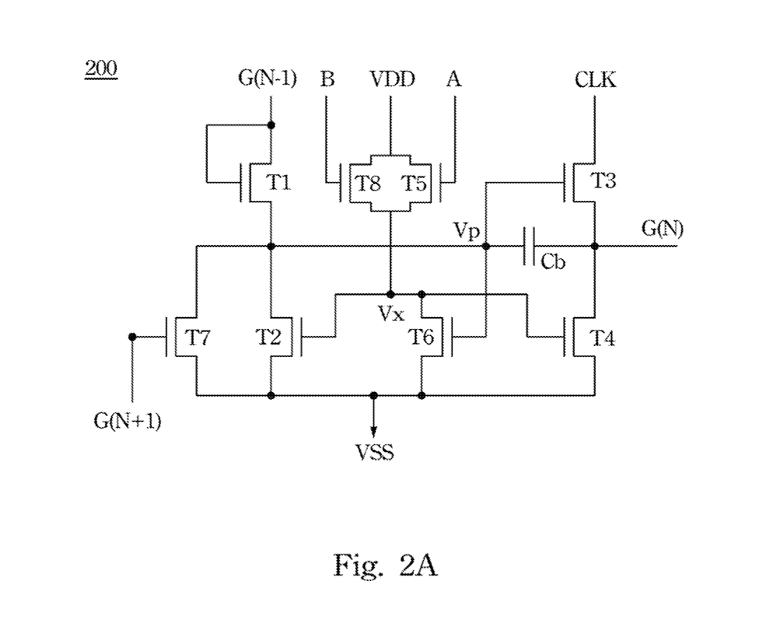

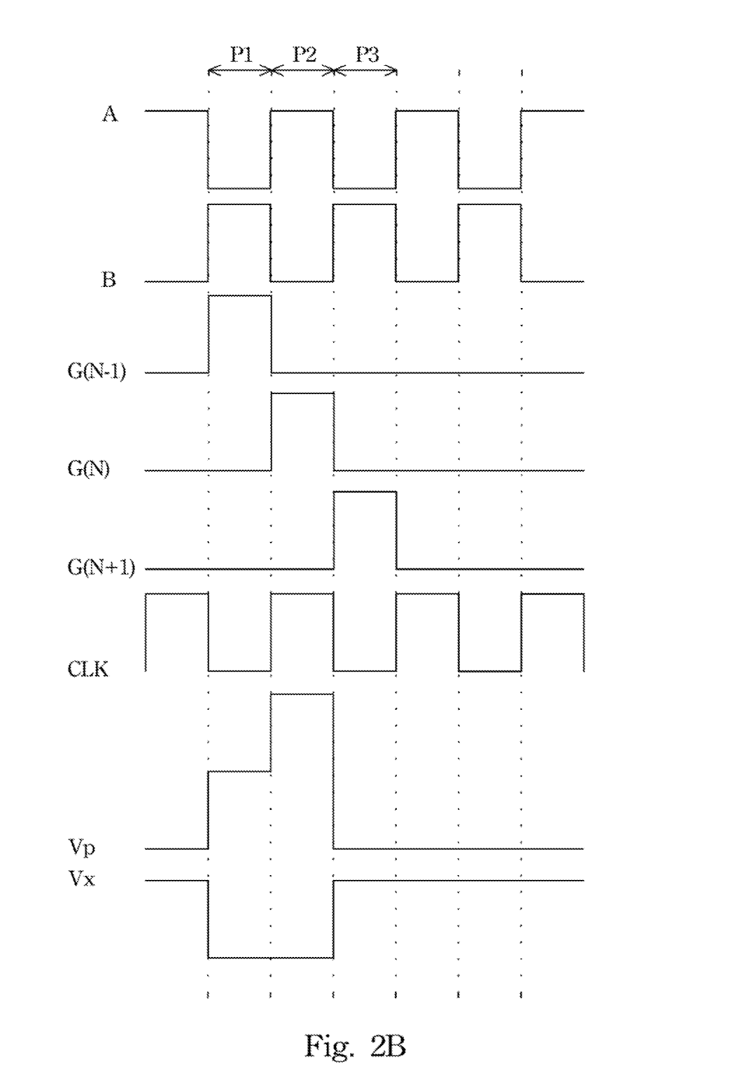

FIG. 2A illustrates a schematic diagram of a driver circuit according to another embodiment of the present invention. The driver circuit 200 includes eight transistors T1, T2, T3, T4, T5, T6, T7 and T8 and a capacitor Cb. The transistors T1, T2, T3, T4, T5, T6, T7 and T8 can be thin film transistors, metal oxide semiconductor field effect transistors or junction field effect transistors. The driver circuit is a gate driver circuit of a display.

The first transistor T1 includes a first end, a second end and a gate end. The first end of the first transistor T1 receives a preceding gate signal G(N−1) from a preceding gate driver circuit. The gate end of the first transistor T1 and the first end of the first transistor T1 are connected together. The second end of the first transistor T1 is connected to the capacitor Cb. Therefore, the capacitor Cb is charged to generate a control signal Vp according to the preceding gate signal G(N−1) received by the first transistor T1.

The second transistor T2 includes a first end, a second end and a gate end. The first end of the second transistor T2 is connected to the second end of the first transistor T1. The gate end of the second transistor T2 receives a control signal Vx. The second end of the second transistor T2 is connected to a low voltage source VSS.

The third transistor T3 includes a first end, a second end and a gate end. The first end of the third transistor T3 receives a clock signal CLK. The gate end of the third transistor T3 receives the control signal Vp. The second end of the third transistor T3 outputs a gate signal G(N). The capacitor Cb is connected to the second end of the third transistor T3 and the gate end of the third transistor T3.

The fourth transistor T4 includes a first end, a second end and a gate end. The first end of the fourth transistor T4 is connected to the second end of the third transistor T3. The gate end of the fourth transistor T4 receives the control signal Vx. The second end of the fourth transistor T4 is connected to the low voltage source VSS.

The fifth transistor T5 includes a first end, a second end and a gate end. The first end of the fifth transistor T5 is connected to the high voltage source VDD. The gate end of the fifth transistor T5 receives a first selection signal A. The second end of the fifth transistor T5 outputs the control signal Vx according to the first selection signal A.

The sixth transistor T6 includes a first end, a second end and a gate end. The first end of the sixth transistor T6 receives the control signal Vx. The gate end of the sixth transistor T6 receives the control signal Vp and is connected to the capacity Cp. The second end of the sixth transistor T6 is connected to the low voltage source VSS.

The seventh transistor T7 includes a first end, a second end and a gate end. The first end of the seventh transistor T7 is connected to the second end of the first transistor T1. The gate end of the seventh transistor T7 receives a next gate signal G(N+1) from a next gate driver circuit. The second end of the seventh transistor T7 is connected to the low voltage source VSS.

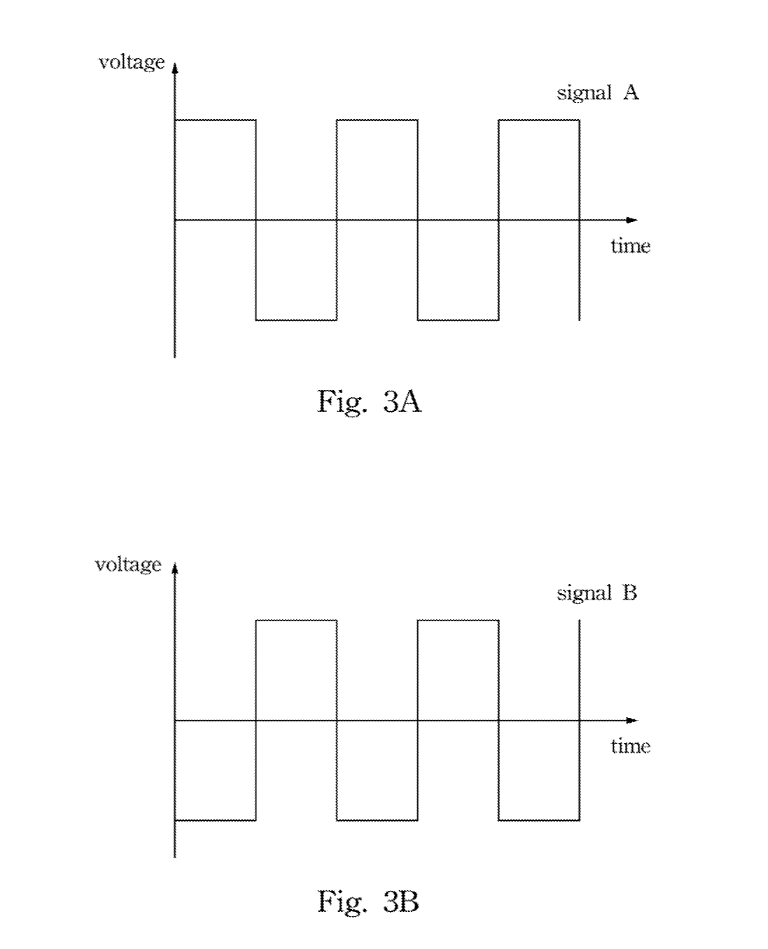

The eighth transistor T8 includes a first end, a second end and a gate end. The first end of the eighth transistor T8 is connected to the high voltage source VDD. The gate end of the eighth transistor T8 receives a second selection signal B. The second end of the eighth transistor T8 outputs the control signal Vx according to the second selection signal B. As illustrated in FIG. 3A and FIG. 3B, the first selection signal A and the second selection signal B are complementary signals.

The fifth transistor T5 is driven by the high-level voltage source VDD. When the high-level voltage source VDD is applied to the fifth transistor T5 for a long time, it is very possible for the threshold voltage of the fifth transistor T5 to be shifted by the high-level voltage source VDD. The shifted threshold voltage affects the time of the fourth transistor T4 which is turned on. Therefore, for preventing the threshold voltage of the fifth transistor T5 from being shifted, in this embodiment, an eighth transistor T8 is used to connect the fifth transistor T5. The eighth transistor T8 and the fifth transistor T5 are connected in parallel. Two complementary signals, the first selection signal A and the second selection signal B, are used to turn on the eighth transistor T8 and the fifth transistor T5 to generate the control signal Vx to improve the reliability of the driver circuit.

FIG. 2B illustrates a timing diagram for operating the driver circuit in FIG. 2A. In time period P1, the fifth transistor T5 is turned on by the second selection signal B. The preceding gate signal G(N−1) from the preceding gate driver circuit is transferred to the first end of the first transistor T1 to turn on the first transistor T1. When the preceding gate signal G(N−1) passes through the first transistor T1, the control signal Vp is pulled up to turn on the sixth transistor T6. Then, the control signal Vx is pulled down by the low voltage source VSS through the turned on sixth transistor T6. The control signal Vp is at a floating state. That is, the voltage level of the control signal Vp is affected by the clock signal CLK through the parasitism capacitor in the third transistor T3. Therefore, in time period P2, when the eighth transistor T8 is turned on by the first selection signal A and when the clock signal CLK is at a high level state, the voltage level of the control signal Vp is increased. Moreover, the control signal Vx is maintained at a low level state by the low voltage source VSS through the turned-on sixth transistor T6 to keep the fourth transistor T4 and the second transistor T2 at an off state. Because the third transistor T3 is turned on when the preceding gate signal G(N−1) is transferred to the first transistor T1, the third transistor T3 outputs the gate signal G(N) synchronized to the clock signal CLK after the preceding gate signal G(N−1). That is, the gate signal G(N) is generated in time period P2. In time period P3, the clock signal CLK is at a low level state and the next gate signal G(N+1) from the next gate driver circuit is transferred to the seventh transistor T7 to turn on the seventh transistor T7. The control signal Vp is pulled down by the low voltage source VSS through the turned-on seventh transistor T7. That is, the control signal Vp is reset.

Accordingly, fewer transistors are used to control the voltage level of the control signal to output a gate signal. The driver circuit structure is simple. Thus, the size of the driver circuit is reduced, and the size of a display panel is also reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A driver circuit, comprising:
a first transistor for receiving a preceding gate signal to generate a first control signal;
a second transistor for pulling down a voltage level of the first control signal according to a second control signal;
a third transistor for receiving a clock signal and outputting the clock signal according to the first control signal;
a fourth transistor for pulling down a voltage level of the clock signal according to the second control signal;
a fifth transistor connected to a high voltage source for outputting the second control signal;
a sixth transistor for pulling down a voltage level of the second control signal according to the first control signal;
a seventh transistor for receiving a next gate signal to pull down the voltage level of the first control signal to turn off the sixth transistor, wherein the voltage level of the second control signal is pulled up when the sixth transistor is turned off; and
a capacitor, wherein the preceding gate signal charges the capacitor to generate the first control signal.

2. The driver circuit of claim 1, wherein the first transistor, the second transistor, the third transistor, the fourth transistor, the fifth transistor, the sixth transistor and the seventh transistor are thin film transistors, metal oxide semiconductor field effect transistors or junction field effect transistors.

3. The driver circuit of claim 1, wherein the voltage level of the second control signal is determined according to the size of the fifth transistor and the size of the sixth transistor.

4. The driver circuit of claim 1, wherein the second control signal is maintained at a high level by the high voltage source through the fifth transistor.

5. The driver circuit of claim 4, wherein
the first transistor includes a first end, a second end and a gate end, wherein the first end of the first transistor receives the preceding gate signal, the gate end of the first transistor is connected to the first end of the first transistor, and the second end of the first transistor outputs the first control signal according to the preceding gate signal;
the second transistor includes a first end, a second end and a gate end, wherein the first end of the second transistor is connected to the second end of the first transistor, the gate end of the second transistor receives the second control signal, and the second end of the second transistor is connected to a low voltage source;
the third transistor includes a first end, a second end and a gate end, wherein the first end of the third transistor receives the clock signal, the gate end of the third transistor receives the first control signal, and the second end of the third transistor outputs the clock signal according to the first control signal;
the fourth transistor includes a first end, a second end and a gate end, wherein the first end of the fourth transistor is connected to the second end of the third transistor, the gate end of the fourth transistor receives the second control signal, and the second end of the fourth transistor is connected to the low voltage source;
the fifth transistor includes a first end, a second end and a gate end, wherein the first end of the fifth transistor is connected to the high voltage source, the gate end of the fifth transistor is connected to the first end of the fifth transistor, and the second end of the fifth transistor outputs the second control signal according to the high voltage source;
the sixth transistor includes a first end, a second end and a gate end, wherein the first end of the sixth transistor receives the second control signal, the gate end of the sixth transistor receives the first control signal, and the second end of the sixth transistor is connected to the low voltage source;
the seventh transistor includes a first end, a second end and a gate end, wherein the first end of the seventh transistor is connected to the second end of is the first transistor, the gate end of the seventh transistor receives the next gate signal, and the second end of the seventh transistor is connected to the low voltage source; and
the capacitor is connected to the second end of the third transistor and the gate end of the third transistor.

6. The driver circuit of claim 1, further comprising:
an eighth transistor connected to the high voltage source, wherein the eighth transistor and the fifth transistor are connected in parallel, the fifth transistor outputs the second control signal according to a first selection signal, and the eighth transistor outputs the second control signal according to a second selection signal, wherein the first selection signal and the second selection signal are complementary signals.

7. The driver circuit of claim 6, wherein the eighth transistor is a thin film transistor, a metal oxide semiconductor field effect transistor or a junction field effect transistor.

8. The driver circuit of claim 6, wherein
the first transistor includes a first end, a second end and a gate end, wherein the first end of the first transistor receives the preceding gate signal, the gate end of the first transistor is connected to the first end of the first transistor, and the second end of the first transistor outputs the first control signal according to the preceding gate signal;
the second transistor includes a first end, a second end and a gate end, wherein the first end of the second transistor is connected to the second end of the first transistor, the gate end of the second transistor receives the second control signal, and the second end of the second transistor is connected to a low voltage source;
the third transistor includes a first end, a second end and a gate end, wherein the first end of the third transistor receives the clock signal, the gate end of the third transistor receives the first control signal, and the second end of the third transistor outputs the clock signal according to the first control signal;
the fourth transistor includes a first end, a second end and a gate end, wherein the first end of the fourth transistor is connected to the second end of the third transistor, the gate end of the fourth transistor receives the second control signal, and the second end of the fourth transistor is connected to the low voltage source;
the fifth transistor includes a first end, a second end and a gate end, wherein the first end of the fifth transistor is connected to the high voltage source, the gate end of the fifth transistor receives the first selection signal, and the second end of the fifth transistor outputs the second control signal according to the first selection signal;
the sixth transistor includes a first end, a second end and a gate end, wherein the first end of the sixth transistor receives the second control signal, the gate end of the sixth transistor receives the first control signal, and the second end of the sixth transistor is connected to the low voltage source;
the seventh transistor includes a first end, a second end and a gate end, wherein the first end of the seventh transistor is connected to the second end of the first transistor, the gate end of the seventh transistor receives the next gate signal, and the second end of the seventh transistor is connected to the low voltage source; and
the eighth transistor includes a first end, a second end and a gate end, wherein the first end of the eighth transistor is connected to the high voltage source, the gate end of the eighth transistor receives the second selection signal, and the second end of the eighth transistor outputs the second control signal according to the second selection signal; and
the capacitor is connected to the second end of the third transistor and the gate end of the third transistor.
